(19) United States
(12) Patent Application Publication
(10) Pub. No.: US 2016/0148865 A1
(43) Pub. Date: May 26, 2016

(54) Electronic Circuit Board, Semiconductor Device Using the Same and Manufacturing Method for the Same

(71) Applicant: Hitachi, Ltd., Tokyo (JP)

(72) Inventors: Kazuaki NAOE, Tokyo (JP); Hiroyuki TENMEI, Tokyo (JP); Masashi NISHIKI, Tokyo (JP)

(21) Appl. No.: 14/898,058

(22) PCT Filed: Aug. 19, 2013
(86) PCT No.: PCT/JP2013/072044

§ 371 Date: Dec. 11, 2015

(51) Int. Cl. H01L 23/498; H01L 21/48; H01L 23/00

(52) U.S. Cl. CPC H01L 23/49838; H01L 23/49894; H01L 24/32; H01L 21/4846; H01L 2224/32225; H01L 2924/05032; H01L 2924/05042; H01L 2924/04642; H01L 2924/05432

(57) ABSTRACT

The present invention aims to provide an electronic circuit board with insulation reliability improved by increasing volume resistivity of a ceramics substrate fabricated by an aerosol deposition method, a semiconductor device using it and a manufacturing method therefor. The present invention provides the electronic circuit board which includes a metal material, and an insulating film formed on a front surface of the metal material and including an inorganic material containing a crystal of a grain diameter of 10 to 20 nm and in which the insulating layer is less than 0.08 g/cm³ in amount of moisture which it contains. In addition, the present invention provides the manufacturing method for the electronic circuit board in which aerosol which contains particles configuring the insulating layer is injected to the metal material to form the insulating layer on the metal material and either the metal material front surface or the insulating layer front surface is heated.

### BACKGROUND The present invention relates to an electronic circuit board, a semiconductor device using it and a manufacturing method therefor.

As the background art of the present technical field, there is Japanese Patent No. 3784341. In this gazette, there is described a circuit board that in the circuit board that a metal material used for cooling has been provided on the back surface side of an insulating ceramics substrate, the ceramics substrate is directly joined to the metal material without using an adhesive under a room temperature environment, the ceramics substrate includes a polycrystalline brittle material, a grain boundary layer including a glass layer is not present on an interface between crystals, and an interface between the ceramics substrate and the metal material is made as an anchor part that the ceramics substrate bites into the metal material.

In Japanese Patent No. 3784341, there is described the electronic circuit board in which the ceramics substrate has been directly formed on the metal material by an aerosol deposition method under the room temperature environment. A conductor property wiring is formed on the front surface of the ceramics substrate in order to load a semiconductor element such as an IC chip and so forth.

However, the inventors and others of the present invention have measured volume resistivity of the ceramics substrate fabricated by the method described in Japanese Patent No. 3784341, and found that it is low in comparison with the volume resistivity of a ceramics substrate fabricated by sintering. Accordingly, a problem has been clarified that when a DC voltage of several 100V has been continuously loaded on the ceramics substrate fabricated by the method described in Japanese Patent No. 3784341, a short-circuit duration is short and the insulation reliability becomes insufficient in comparison with the ceramics substrate fabricated by sintering.

### SUMMARY

In view of the abovementioned problem, the present invention aims to provide an electronic circuit board in which the volume resistivity of the ceramics substrate which has been fabricated by the aerosol deposition method is increased and the insulation reliability has been improved, a semiconductor device using it and a manufacturing method therefor.

In order to solve the abovementioned problem, the present invention provides an electronic circuit board which includes a metal material and an insulating layer which has been formed on a front surface of the metal material and includes an inorganic material containing a crystal of a grain diameter of 10 to 20 nm and in which the insulating layer is less than 0.08 g/cm³ in amount of moisture which it contains.

In addition, the present invention provides a manufacturing method for electronic circuit boards in which aerosol which contains particles configuring an insulating layer is injected to a metal material to form the insulating layer on a front surface of the metal material, and either the metal material front surface or the insulating layer front surface is heated.

According to the present invention, there can be provided the electronic circuit board in which the volume resistivity of the ceramics substrate which has been fabricated by the aerosol deposition method is increased and the insulation reliability has been improved, the semiconductor device using it and the manufacturing method therefor.

### BRIEF DESCRIPTION OF THE DRAWINGS

FIG. 1 is a schematic diagram of an electronic circuit board in a first embodiment;

FIG. 2 is a configurational explanatory diagram of an aerosol deposition device;

FIG. 3 is a schematic diagram of a semiconductor device using the electronic circuit board in the first embodiment; and

FIG. 4 is a schematic diagram of a structure fabrication device in an altered example 1 of the first embodiment.

### DETAILED DESCRIPTION

In the following, an embodiment will be described using the drawings.

### First Embodiment

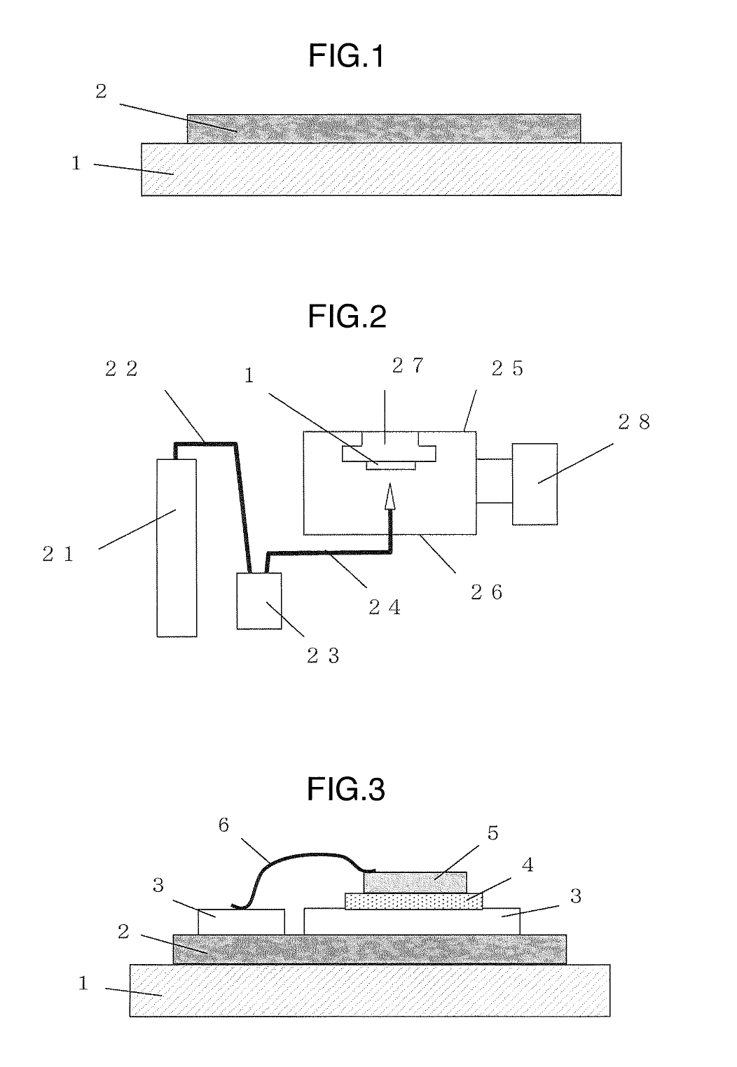

A schematic diagram of an electronic circuit board in the present embodiment is shown in FIG. 1. An insulating layer 2 including an inorganic material is formed on a front surface of a metal material 1. A fin for improving heat dissipation may be formed on one surface of the metal material 1 on which the insulating layer 2 is not formed. The insulating layer 2 is formed by the aerosol deposition method, contains crystal grains of a size of 10 to 20 nm, and is directly formed on the front surface of the metal material 1 with no adhesive layer such as grease, brazing filler metal and so forth.

As the inorganic material to be used in the insulating layer 2, any material can be used if it is electrically insulating. For example, Al₂O₃, AlN, TiO₂, Cr₂O₃, SiO₂, Y₂O₃, NiO, ZrO₂, SiC, Tic, WC and so forth are given. The inorganic material to be used in the insulating layer 2 may be a mixture of them. Form the point of a high thermal conductivity, SiC, AlN, Si₃N₄, Al₂O₃ and so forth are desirable. Further, in the points of handling in the atmosphere and manufacturing cost of the inorganic material, Al₂O₃ is the most desirable.

A feature of the present embodiment is that an amount of moisture contained in the insulating layer 2 is less than 0.08 g/cm³. In the conventional structure described in Japanese Patent No. 3784341, since the insulating layer is formed under the room temperature environment, moisture which is present in the surroundings is adsorbed to, contained in the insulating layer and the volume resistivity of the insulating layer is lowered under the influence of the moisture contained therein. There is such a problem that the lower the volume resistivity is, the shorter becomes the short-circuit duration when a constant voltage has been continuously applied to the insulating layer, and the insulation reliability of the electronic circuit board cannot be ensured. On the other hand, in the present embodiment, the volume resistivity is increased by reducing the amount of moisture contained to less than 0.08 g/cm³ and the insulation reliability can be improved.

In the present embodiment, a process of forming the insulating layer 2 on the front surface of the metal material 1 by the aerosol deposition method will be described. A configurational explanatory diagram of an aerosol deposition device is shown in FIG. 2. A high-pressure gas cylinder 21 is uncapped and a carrier gas is introduced into an aerosol generator 23 via a carrier pipe 22. Particles which configure the insulating layer 2 are put into the aerosol generator 23 in advance. It is desirable that the grain diameter be about 0.1 to 5 μm. The aerosol which contains the particles concerned is generated by being mixed with the carrier gas. The metal material 1 is fixed to a stage 27 in a vacuum chamber 25. A pressure difference is generated between the aerosol generator 23 into which the carrier gas is to be introduced and the vacuum chamber 25 by reducing the pressure in the vacuum chamber 25 by a vacuum pump 28. Owing to this pressure difference, the aerosol is ejected toward the metal material 1 through a carrier pipe 24 and a nozzle 26. The particles in the aerosol collide with the metal material 1 and are combined therewith. Further, the particles continuously collide therewith, also the particles are mutually combined and thereby the insulating layer 2 is formed on the front surface of the metal material 1.

Moisture which has been adhered to a chamber inner wall, moisture contained in the carrier gas, moisture which has been adhered to raw material particles remain in the vacuum chamber. In a case where this remaining moisture has adsorbed to the front surface of the insulating layer which is being formed, the moisture remains in the insulating layer. In order to reduce the moisture in the insulating layer, it is necessary to prevent adsorption of the moisture by heating the metal material which forms the insulating layer or the front surface of the insulating layer which is being formed. As methods therefor, there are, for example, irradiation of the insulating layer front surface with microwaves, heating of the metal material and the carrier gas by a heater and so forth. Since the vacuum chamber is under reduced pressure, a heating temperature may be not more than 100° C. which is the boiling point of water in the atmosphere. For example, in a case where the pressure in the vacuum chamber during formation of the insulating layer is several ten to several hundred Pa, it is possible to remove the moisture by setting the heating temperature to at least about 50° C. In addition, in a case where it is necessary to perform moisture removal in a short period of time, the heating temperature may be set to at least 100° C. At this time, film peeling caused by oxidation and thermal stress on the metal surface can be prevented by setting the heating temperature to not more than 150° C.

A relationship between the moisture content and the volume resistivity of the insulating layer 2 of the electronic circuit board fabricated in the present embodiment is evaluated. The relationship among the heating temperature of the metal material, the moisture content and the volume resistivity of the insulating layer 2 is shown in Table 1.

TABLE 1

| | Well- | | | | |
|---|---|---|---|---|---|
| | known | | | | |
| | Example | Present Invention | | | |
| Heating | (not | 50 | 75 | 100 | 125 |
| Temperature | heated) | | | | |
| (° C.) | | | | | |
| Amount of | 0.11 | 0.08 | 0.07 | 0.07 | 0.06 |
| Moisture | | | | | |
| (g/cm³) | | | | | |
| Volume | 1.4 × 10⁷ | 1.0 × 10⁸ | 11 × 10⁸ | 2.5 × 10⁸ | 4.3 × 10⁸ |
| Resistivity | | | | | |
| (Ωm) at | | | | | |
| 85° C. | | | | | |

For the moisture content, an H amount H is measured by secondary ion mass spectrometry and the H amount is converted into the moisture (H₂O) amount. In measurement of the H amount, in order to avoid the influence of the moisture adhered to the front surface of the insulating layer 2, a measurement point is etched off by about 500 nm by ion sputtering treatment and thereafter measurement of 3 μm is performed in a film thickness direction of the insulating layer 2. Cs⁺ ions of 5.0 kV in accelerating voltage are used as primary ions. A measuring region is 39 μm×39 μm. In addition, for measurement of the volume resistivity of the insulating layer 2, a circular electrode of 15 mm in diameter is formed on the insulating layer 2 with silver paste. A DC voltage of 100V is applied between the electrode and the metal material 1 and an electric resistance value is calculated from a current value obtained one minute after voltage application at which the current value is stabilized. A measurement temperature is 85° C. The volume resistivity is converted from this electric resistance value, an electrode area, a thickness of the insulating layer. In formation of the insulating layer, the insulating layer of 20 μm in film thickness is formed by the aerosol deposition method using normal soda easily sinterable Al₂O₃ particles of 2.5 μm in central particle diameter. The carrier gas is N₂ and a gas flow rate is 4 L/min. For the metal material, a plate-shaped tough-pitch copper of 3 mm in thickness is used. As a method of removing the moisture, heating of the metal material is performed in formation of the insulating layer. Heating temperatures are 50° C., 75° C., 100° C., 125° C. In a conventional structure that the insulating layer is formed at room temperatures, the moisture amount is 0.11 g/cm³, the volume resistivity is 1.4×10⁷ Ω·m. On the other hand, in the present embodiment that the metal material is heated, the amount of moisture is less than 0.11 g/cm³. In particular, for the amount of moisture of not more than 0.08 g/cm³, it is confirmed that the volume resistivity is at least 1.0×10⁸ Ω·m, the insulating layer of the present embodiment is increased by about one digit in volume resistivity and is improved in insulation reliability in comparison with the conventional structure.

An example of a semiconductor device using the electronic circuit board in the present embodiment is shown in FIG. 3. A conductor property wiring 3 is formed on one surface of the insulating layer 2 to which the metal material 1 is not joined. As a method of forming the conductor property wiring 3, any of well-known methods such as a vacuum vapor deposition method, a sputtering method, a CVD method, a plating method, a screen printing method and so forth can be used. A semiconductor element 5 is connected to the conductor property wiring 3 via a joining member 4. In addition, as the joining member 4, solder of Pb—Sn system, Sn—Cu system, Sn—Ag—Cu system and so forth, metals such as Ag and so forth and metal filler containing resins and so forth are given. An upper surface of the semiconductor element 5 and the conductor property wiring 3 are connected together by a metal wire 6 such as Au, Al and so forth. When reliability in connection between the semiconductor element 5 and the metal wire 6 is insufficient under the influence of a thermal stress generated by heat generation and cooling of the semiconductor element, a metal ribbon such as Al, Cu and so forth with which a connection area can be expanded may be used, in place of the metal wire 6.

In the electronic circuit board in the present embodiment, in addition to improvement of the insulation reliability of the semiconductor device, a heat dissipation characteristic of the semiconductor device is improved and thereby operational reliability of the semiconductor element is also improved. In the insulating layer (1.4×10⁷ Ω·m in volume resistivity) of the conventional structure, in a case where the insulation resistance of the insulating layer of, for example, at least 10⁸ Ω is needed, the film thickness of 710 μm is needed (assuming that a formation area of the insulating layer is 1 cm²). However, in the present embodiment, since the volume resistivity is increased (1.0×10⁸ Ω·m in volume resistivity), the insulation resistance of 10⁸ Ω can be realized with the film thickness of 100 μm. Since the necessary film thickness is reduced to not more than 1/7 and the thermal resistance of the insulating layer is also reduced to not more than 1/7 in comparison with the conventional structure, the heat dissipation characteristic of the semiconductor device is improved.

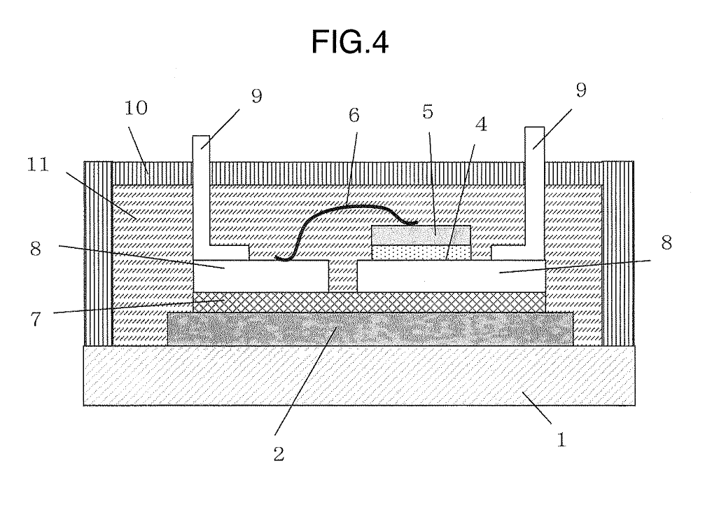

Another example of the semiconductor device using the electronic circuit board in the present embodiment is shown in FIG. 4. This semiconductor device can be utilized as a power module loaded with a power semiconductor such as an IGBT and so forth for handling a large current of about several A to several hundred A. By applying the insulating layer which has been improved in volume resistivity and is less than 0.08 g/cm³ in moisture amount, the insulating reliability and the heat dissipation characteristic of the semiconductor device are improved also in a case where the power semiconductor has been loaded on the semiconductor element.

Low specific resistance and a thickness for lowering the electric resistance and reducing losses caused by Joule heat are required for a metal conductor plate 8 used in the power module. The thickness of a metal conductor has an effect of not only lowering the electric resistance but also diffusing generated heat of the semiconductor element in the metal conductor plate 8 and then making a heat flux which flows to the metal material small, and also contributes to reduction in thermal resistance of the semiconductor device. In the power module, use of a conductor of several 100 μm to several mm in thickness, not more than 3 μΩ·cm which is the same as an Al alloy plate material in specific resistance is desirable from the viewpoint of a working current and diffusion of the generated heat. In order to realize such a conductor, in the example shown in FIG. 4, the metal conductor plate 8 is adhered to the insulating layer 2 via a resin layer 7. The metal conductor plate 8 is a metal plate including an Al alloy, a Cu alloy and so forth. The metal conductor having an optional thickness can be formed by working in advance the metal conductor plate 8 to be adhered. A front surface of the metal conductor plate 8 maybe subjected to plating for rust prevention and surface treatment such as roughening, oxidation treatment and so forth in order to improve force of adhesion with the resin layer 7.

As resins for the resin layer 7, epoxy resins, phenol resins, fluorine-based resins, silicon resins, polyimide resins, polyamide resins, polyamide-imide resins and so forth are given. As an application method for the resin layer 7, any of well-known methods such as the screen printing method, an inkjet method, a roll coater method, a dispenser method and so forth can be used. In addition, the resin layer 7 may be formed by arranging a sheet-shaped resin between the insulating layer 2 and the metal conductor plate 8 and making them adhere together by thermo-compression bonding. Thickness control of the resin layer 7 is facilitated by using the sheet having a desired thickness. In addition, the resin layer 7 may contain insulating inorganic particles of Al₂O₃, AlN, SiO₂ and so forth as fillers. By containing the inorganic particles, the thermal conductivity of the resin layer 7 is improved. When the thermal conductivity of the resin layer 7 is improved, temperature rising of the semiconductor element which is in operation can be suppressed and therefore the operational reliability of the semiconductor device is improved.

The semiconductor element 5 is connected to the metal conductor plate 8 via the joining member 4. As the semiconductor element 5, the power semiconductor elements such as the IGBT and so forth for converting a DC current to an AC current by a switching operation, and a semiconductor element for use in a control circuit for controlling these power semiconductor elements are given. In addition, as the joining member 4, the solder of Pb—Sn system, Sn—Cu system, Sn—Ag—Cu system and so forth, the metals such as Ag and so forth and the metal filler containing resins and so forth are given. The upper surface of the semiconductor element 5 and the metal conductor plate 8 are connected together by the metal wire 6 such as Al and so forth. When the reliability in connection between the semiconductor element 5 and the metal wire 6 is insufficient under the influence of the thermal stress generated by heat generation and cooling of the semiconductor element, the metal ribbon such as Al, Cu and so forth with which the connection area can be expanded may be used, in place of the metal wire 6. An external connection terminal 9 is connected to the metal conductor plate 8. A resin case 10 is adhered around the metal plate 1 and a sealing agent 11 such as an insulating gel agent and so forth is packed into it.

Incidentally, the present invention is not limited to the abovementioned embodiment and various altered examples are included therein. For example, the abovementioned embodiment has been described in detail in order to comprehensibly describe the present invention and it is not necessarily limited to the ones which possess all of the described configurations. In addition, it is also possible to replace part of a configuration of one embodiment with a configuration of another configuration, and, in addition, it is also possible to add a configuration of another embodiment to a configuration of one embodiment. In addition, it is possible to perform addition, deletion, and replacement of another configuration in regard to part of a configuration of each embodiment.

1. An electronic circuit board, comprising:
a metal material; and
an insulating layer which has been formed on a front surface of the metal material and includes an inorganic material containing a crystal of a grain diameter of 10 to 20 nm,
wherein the insulating layer is less than 0.08 g/cm³ in amount of moisture which it contains.

2. The electronic circuit board according to claim 1, wherein volume resistivity of the insulating layer at 85° C. is at least 1.0×10⁸ Ωm.

3. The electronic circuit board according to claim 1, wherein the insulating layer contains any of SiC, AIN, Si₃N₄, Al₂O₃.

4. A semiconductor device, comprising:
the electronic circuit board according to claim 1;
a conductor property wiring which has been formed on the electronic circuit board; and
a semiconductor element which has been connected with the conductor property wiring by a joining member.

5. A semiconductor device, comprising:
the electronic circuit board according to claim 1;
a metal conductor plate which has been formed on the electronic circuit board via a resin layer; and
a semiconductor element which has been connected with the metal conductor plate by a joining member.

6. A manufacturing method for electronic circuit boards,
wherein aerosol which contains particles configuring an insulating layer is injected to a metal material to form the insulating layer on a front surface of the metal material; and
either the metal material front surface or the insulating layer front surface is heated.

7. The manufacturing method for electronic circuit boards according to claim 6, wherein either the metal material front surface or the insulating layer front surface is heated at a temperature of 50 degrees to 150 degrees.

8. The manufacturing method for electronic circuit boards according to claim 6, wherein either the metal material front surface or the insulating layer front surface is heated in a vacuum chamber.

9. The manufacturing method for electronic circuit boards according to claim 6, wherein either the metal material front surface or the insulating layer front surface is heated by microwave irradiation or a heater.
